(19) United States
(12) Patent Application Publication
(10) Pub. No.: US 2006/0008939 A1
(43) Pub. Date: Jan. 12, 2006

(54) Image sensor package

(76) Inventors: Abnet Chen, Hsinchu Hsien (TW); Tony Wang, Hsinchu Hsien (TW); Chung Hsien Hsin, Hsinchu Hsien (TW); Figo Hsieh, Hsinchu Hsien (TW)

Correspondence Address: PRO-TECHTOR INTERNATIONAL, 20775 Norada Court, Saratoga, CA, 95070-3018, US

(21) Appl. No.: 10/887,577

(22) Filed: Jul. 8, 2004

(51) Int. Cl. H01L 21/00

(52) U.S. Cl. 438/65

(57) ABSTRACT

An image sensor package includes a substrate, a frame layer, a photosensitive chip, wires, and transparent layer. The substrate has an upper surface on which first electrodes are formed, and a lower surface on which second electrodes are formed, wherein the each first electrode is curved. The frame layer is arranged on the upper surface of the substrate to form a cavity together with the substrate. The photosensitive chip is arranged within the cavity and is mounted on the upper surface of the substrate. The plurality of wires are electrically connected the photosensitive chip to the first electrode of the substrate. The transparent layer is covered over the frame layer to cover the photosensitive chip.

### BACKGROUND OF THE INVENTION

1. Field of the invention

The invention relates to an image sensor package, and in particular to an image sensor is capable of increasing the reliability of the product.

2. Description of the Related Art

Referring to FIG. 1, it is a conventional image sensor includes a substrate 10, a frame layer 18, a photosensitive chip 26, a plurality of wires 28, and a transparent layer 34.

The substrate 10 has a first surface 12 on which a plurality of first electrodes 15 are formed, and a second surface 14 on which a plurality of second electrodes 16 are formed. The first electrodes 15 are corresponding to electrically connect to the second electrodes 16 by the conductive wires 17, which are located at the side of the substrate. The frame layer 18 has an upper surface 20 and a lower surface 22 adhered to the first surface 12 of the substrate 10 to form a chamber 24 together with the substrate 10. The photosensitive chip 26 is arranged within the chamber 24, and is mounted to the first surface 12 of the substrate 10. Each wire 28 has a first terminal 30 and a second terminal 32. The first terminals 30 are electrically connected to the photosensitive chip 26, and the second terminals 32 are electrically connected to the first electrodes 15 of the substrate 10. The transparent layer 34 is adhered to the upper surface 20 of the frame layer 18.

Referring to FIG. 2, it is a top view of the substrate of the FIG. 1. The each electrode 15 of the substrate 10 is arranged in straight line, and a green paint 35 is coated between the each first electrode 15. The frame layer 18 is mounted on the green paint 35. Therefore, The wet-air from the atmosphere air will enter the internal of the product through the gap between the green paint 35 and first electrode 15, so that the reliability of the product may be reduced.

### SUMMARY OF THE INVENTION

An object of the invention is to provide an image sensor package, it can prevent the wet-air from the atmosphere air to inter the internal of the product. So as to, may be enhanced the reliability of the product

To achieve the above-mentioned object, the invention provides a substrate, a frame layer, a photosensitive chip, wires and transparent layer. The substrate has an upper surface on which first electrodes are formed, and a lower surface on which second electrodes are formed, wherein the each first electrode is curved. The frame layer is arranged on the upper surface of the substrate to form a cavity together with the substrate. The photosensitive chip is arranged within the cavity and is mounted on the upper surface of the substrate. The plurality of wires are electrically connected the photosensitive chip to the first electrode of the substrate. The transparent layer is covered over the frame layer to cover the photosensitive chip.

### BRIEF DESCRIPTION OF THE DRAWINGS

FIG. 1 is a cross-sectional view showing a conventional image sensor package.

FIG. 2 is a top-view showing an conventional image sensor package.

FIG. 3 is a cross-sectional view showing an image sensor package of the present invention.

FIG. 4 is a top-view showing a substrate of image sensor package of the present invention

FIG. 5 is a top-view showing an image sensor package of the present invention

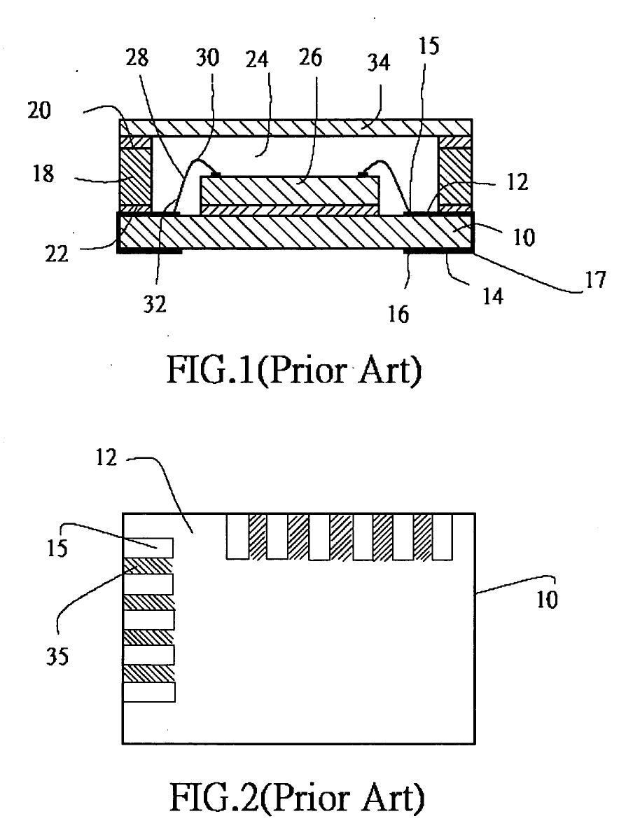

### DETAILED DESCRIPTION OF THE INVENTION

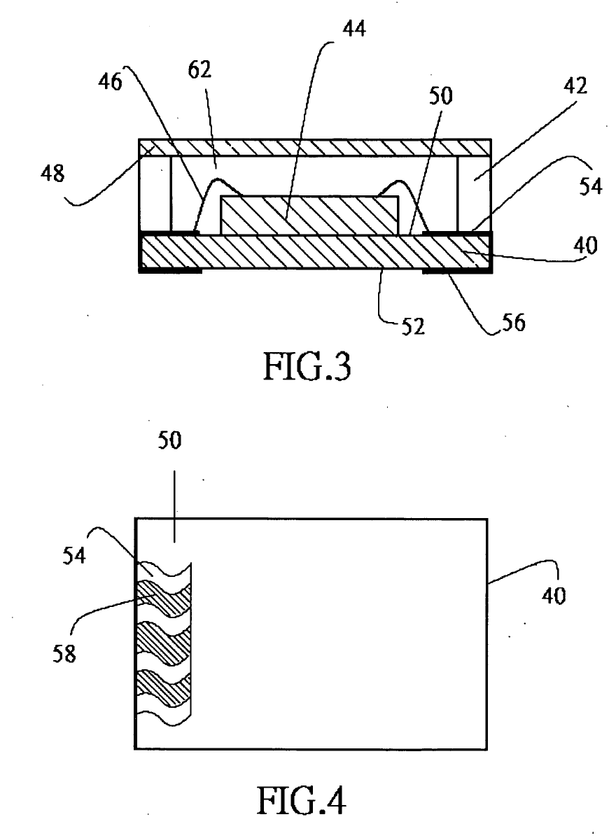

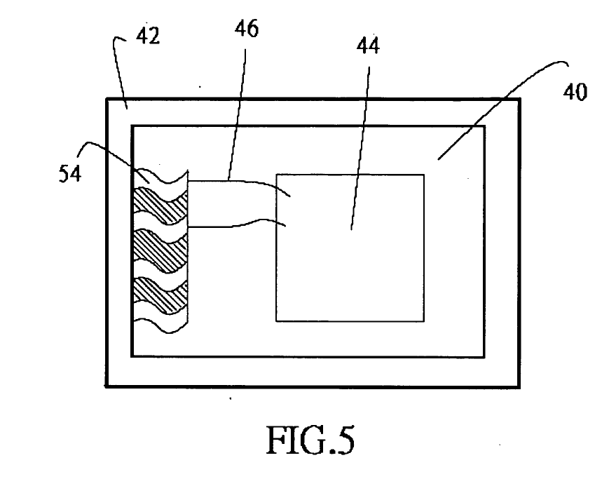

Please refer to FIG. 3, FIG. 4, and FIG. 5, it is an image sensor package of the present invention includes a substrate 40, a frame layer 42, a photosensitive chip 44, wires 46, and a transparent layer 48.

The substrate 40 has an upper surface 50 on which first electrodes 54 are formed, and a lower surface 52 on which second electrodes 56 are formed. The first electrodes 54 are corresponding to electrically connect to the second electrode 56, wherein the each first electrode 54 is curved, in the embodiment, the each first electrode 54 is S-shape. A green-paint 58 is coated between the each first electrode 54 of the substrate 40.

The frame layer 42 is arranged on the upper surface 50 of the substrate 40 to form a cavity 62 together with the substrate 40.

The photosensitive chip 44 is arranged within the cavity 62 and is mounted on the upper surface 50 of the substrate 40.

The plurality of wires 46 are electrically connected the photosensitive chip 44 to the first electrode 54 of the substrate 40.

The transparent layer 48 is covered over the frame layer 42 to cover the photosensitive chip 44.

Therefore, the first electrodes man prevent the wet-air to enter the internal of the product, thus, the reliability of the product may be enhanced.

While the invention has been described by way of an example and in terms of a preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

What is claimed is:

1. An image sensor package, the package comprising:
a substrate having an upper surface on which first electrodes are formed, and a lower surface on which second electrodes are formed, the first electrodes are corresponding to electrically connect to the second electrode, wherein the each first electrode is curved;
a frame layer arranged on the upper surface of the substrate to form a cavity together with the substrate;
a photosensitive chip arranged within the cavity and mounted on the upper surface of the substrate;
a plurality of wires electrically connected the photosensitive chip to the first electrode of the substrate; and
a transparent layer covered over the frame layer to cover the photosensitive chip.

2. The image sensor package according to claim 1, wherein a green-paint is coated between the each first electrode of the substrate.

3. The image sensor package according to claim 1, wherein the each first electrode is S-shape.
